(19) United States
(12) Patent Application Publication
(10) Pub. No.: US 2011/0267796 A1
(43) Pub. Date: Nov. 3, 2011

(54) NONVOLATILE MEMORY DEVICE AND METHOD FOR MANUFACTURING THE SAME

(76) Inventors: Atsushi YOSHIMURA, Kanagawa-ken (JP); Yasuo Tane, Mie-ken (JP)

(21) Appl. No.: 13/051,880

(22) Filed: Mar. 18, 2011

(30) Foreign Application Priority Data
Apr. 28, 2010 (JP) 2010-104316

(51) Int. Cl. H01L 23/12; B32B 37/14; B32B 37/06; H01L 21/00; B32B 37/12

(52) U.S. Cl. 361/820; 156/295

(57) ABSTRACT

According to one embodiment, a semiconductor device includes a matrix and a semiconductor element bonded to the matrix via a bonding layer. The bonding layer includes a first layer and a second layer having a viscosity lower than a viscosity of the first layer at a bonding temperature. The first layer has a portion in which an end of the first layer is set further back to an inside than an end of the semiconductor element. At least a part of the portion set back to the inside is filled with a part of the second layer extruded from a periphery of the first layer to an outside.

### CROSS-REFERENCE TO RELATED APPLICATIONS

This application is based upon and claims the benefit of priority from the prior Japanese Patent Application No. 2010-104316, filed on Apr. 28, 2010; the entire contents of which are incorporated herein by reference.

### FIELD

Embodiments described herein relate generally to a nonvolatile memory device and a method for manufacturing the same.

### BACKGROUND

A technology has thus far been known in which a bonding layer is formed on one surface (e.g. the back surface (the surface opposite to a surface in which a circuit pattern is formed)) of a semiconductor element (a semiconductor chip) and the semiconductor element is bonded to a matrix (e.g. a substrate, a lead frame, another semiconductor element, etc.) via the bonding layer.

Here, when the semiconductor element is fragmentated using the blade dicing method or the like, a peripheral portion of the bonding layer may break off or something to cause a recess at the periphery of the bonding layer. Since such a recess remains after the semiconductor element is bonded to the matrix, the recess may cause a decrease in the reliability of the semiconductor device.

### BRIEF DESCRIPTION OF THE DRAWINGS

FIGS. 1A and 1B are schematic views for illustrating a semiconductor device according to a first embodiment;

FIGS. 2A and 2B are schematic views for illustrating a semiconductor device according to a comparative example;

FIG. 3 is a schematic view for illustrating a semiconductor device according to the comparative example;

FIGS. 4A to 4C are schematic cross-sectional views for illustrating the case of an application to a semiconductor device of a stacked multichip structure;

FIGS. 5A and 5B are schematic views for illustrating a semiconductor device according to a first modification;

FIGS. 6A and 6B are schematic views for illustrating a semiconductor device according to a second modification;

FIGS. 7A and 7B are schematic views for illustrating a semiconductor device according to a third modification;

FIG. 8A is a schematic view for illustrating a semiconductor device according to a comparative example, and

FIG. 8B is a schematic view for illustrating a semiconductor device according to a fourth modification;

FIG. 9A is a schematic view before bonding to the matrix, and FIG. 9B is a schematic view after bonding to the matrix;

FIG. 10 is a flow chart illustrating a method for manufacturing a semiconductor device according to a second embodiment; and

FIG. 11 is a flow chart illustrating a method for manufacturing a semiconductor device according to a second modification.

### DETAILED DESCRIPTION

In general, according to one embodiment, a semiconductor device includes a matrix and a semiconductor element bonded to the matrix via a bonding layer. The bonding layer includes a first layer and a second layer having a viscosity lower than a viscosity of the first layer at a bonding temperature. The first layer has a portion in which an end of the first layer is set further back to an inside than an end of the semiconductor element. At least a part of the portion set back to the inside is filled with a part of the second layer extruded from a periphery of the first layer to an outside.

In general, according to one embodiment, a method is disclosed for manufacturing a semiconductor device including bonding a matrix and a semiconductor element via a bonding layer. The method can include forming a first layer that forms the bonding layer. The method can include forming a second layer having a viscosity lower than a viscosity of the first layer that forms the bonding layer at a bonding temperature. The first layer is formed so that an end of the first layer has a portion set further back to an inside than an end of the semiconductor element. At least a part of the portion set back to the inside is filled with a part of the second layer extruded from a periphery of the first layer to an outside in bonding the matrix and the semiconductor element via the bonding layer.

Various embodiments will be described hereinafter with reference to the accompanying drawings. In the drawings, like components are marked with the same reference numerals and a detailed description thereof is omitted as appropriate.

### FIRST EMBODIMENT

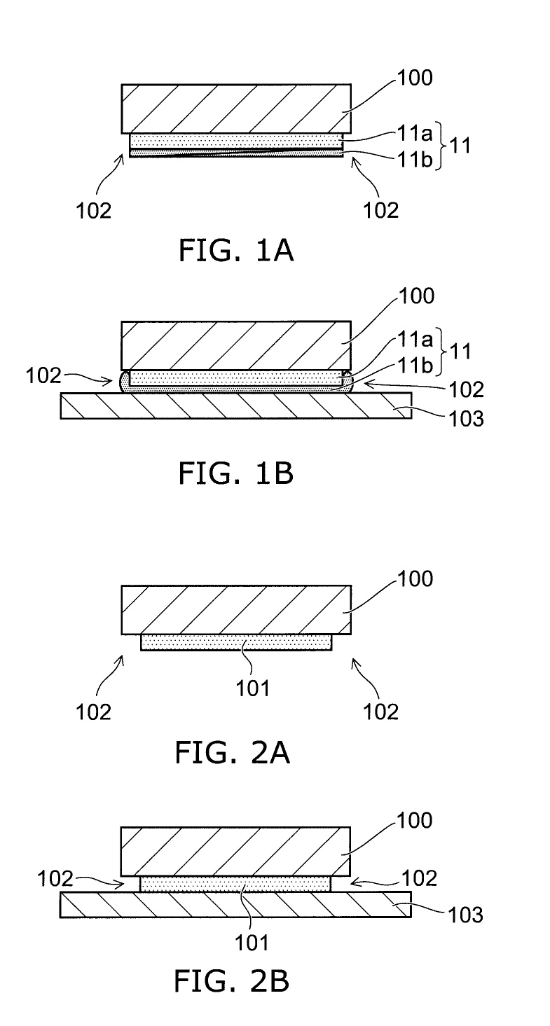

FIGS. 1A and 1B are schematic views for illustrating a semiconductor device according to a first embodiment. FIG. 1A is a schematic view before bonding to a matrix, and FIG. 1B is a schematic view after bonding to the matrix.

FIGS. 2A and 2B are schematic views for illustrating a semiconductor device according to a comparative example. FIG. 2A is a schematic view before bonding to a matrix, and FIG. 2B is a schematic view after bonding to the matrix.

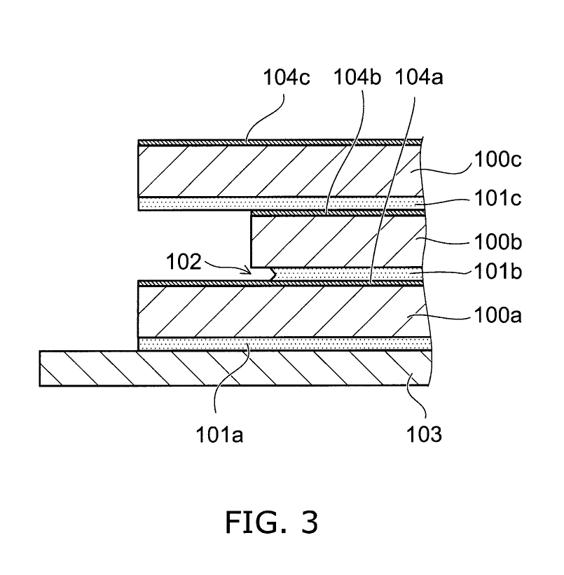

FIG. 3 is a schematic view for illustrating a semiconductor device according to the comparative example, and is a schematic view illustrating the case where a plurality of semiconductor elements are stacked.

First, the semiconductor device according to the comparative example will now be illustrated.

A semiconductor element has been conventionally bonded to a matrix such as a lead frame with a resin paste and the like in the die bonding process. According to such a method, however, the semiconductor element is bonded obliquely or bonded out of alignment, and therefore high-precision bonding cannot be performed. Furthermore, the control of the thickness of a bonding layer is difficult as well.

In view of this, these days a bonding layer is formed on one surface (e.g. the back surface (the surface opposite to a surface in which a circuit pattern is formed)) of the semiconductor element, and the semiconductor element is bonded to the matrix via the bonding layer.

Although the semiconductor element in which the bonding layer like this is formed can be manufactured also by forming a bonding layer on one surface of a fragmentated semiconductor element, such a manufacturing method may decrease productivity.

In this regard, there is a case where a bonding layer is formed on one surface of a wafer and the blade dicing method or the like is used to divide the wafer in which the bonding layer is formed; thereby, the semiconductor element in which the bonding layer is formed is manufactured.

Here, when the wafer in which the bonding layer is formed is divided using the blade dicing method or the like, a peripheral portion of the bonding layer may break off or something to cause a recess at the periphery of the bonding layer.

Also in the case where the bonding layer is formed on one surface of the fragmentated semiconductor element, a recess may occur at the periphery of the bonding layer.

In this case, the recess refers to a portion in which an end of the bonding layer is set further back to the inside than the end of the semiconductor element. The recess may occur at part of the periphery of the bonding layer, or the entire periphery of the bonding layer may be set further back to the inside than the end of the semiconductor element to cause the recess. The number of recesses is not specifically limited and may be one or plural numbers. Also the size, location, distribution, and the like of the recess are not specifically limited.

Such a recess remains after the semiconductor element is bonded to the matrix.

For example, if there is a recess 102 at the periphery of a bonding layer 101 formed on one surface of a semiconductor element 100 as shown in FIG. 2A, the recess 102 remains after the semiconductor element 100 is bonded to a matrix 103, as shown in FIG. 2B.

Therefore, for example, there is a concern that a resin may not be buried in the recess 102 during the sealing process and a void is generated, or delamination may occur if the adhesive force of the bonding layer is weak. That is, a decrease in the reliability of the semiconductor device may be caused.

What is illustrated in FIGS. 2A and 2B is the case where the semiconductor element 100 is bonded to the substrate via the bonding layer 101, but the foregoing is applied also to the case where the semiconductor element 100 is bonded to another semiconductor element via the bonding layer 101.

For example, even in the case where, as shown in FIG. 3, a semiconductor element 100a is bonded to a substrate via a bonding layer 101a, a semiconductor element 100b is bonded to the semiconductor element 100a via a bonding layer 101b, and a semiconductor element 100c is bonded to the semiconductor element 100b via a bonding layer 101c, if there is the recess 102 at the periphery of the bonding layer 101b, the recess 102 remains after bonding. That is, even in the case of what is called a stacked multichip package structure, the recess 102 remains after bonding and this may cause a decrease in the reliability of the semiconductor device similarly to what is illustrated in FIGS. 2A and 2B. 104a to 104c in FIG. 3 are surface protection films.

In this case, if the viscosity of the bonding layer at the bonding temperature is set to such a viscosity as causes a prescribed fluidity, at least part of the recess 102 can be filled with part of the bonding layer extruded during bonding. However, if the viscosity of the bonding layer at the bonding temperature is set to such a viscosity as causes fluidity, since the semiconductor element is bonded obliquely or bonded out of alignment, high-precision bonding cannot be performed. Furthermore, the control of the thickness of the bonding layer is difficult as well.

Next, the embodiment is illustrated referring to FIGS. 1A and 1B again.

In the embodiment, the bonding layer is formed of a plurality of layers with different viscosities at the bonding temperature.

For example, as shown in FIG. 1A, a bonding layer 11 is formed by stacking a layer 11a (first layer) and a layer 11b (second layer). The layer 11b is configured to have a viscosity lower than the viscosity of the layer 11a at the bonding temperature.

In this case, the viscosity of the layer 11a at the bonding temperature may be such a viscosity as does not cause fluidity at the bonding temperature. The viscosity of the layer 11b at the bonding temperature may be such a viscosity as causes a certain level of fluidity at the bonding temperature.

The known viscosity measurement method provided in Japanese Industrial Standard JIS K 7244-10, for example, may be used for the measurement of the viscosity. In this case, a dynamic viscoelasticity measurement apparatus (a parallel plate oscillatory rheometer) or the like may be used to measure the viscosity.

When the semiconductor element 100 is bonded to the matrix 103 via the bonding layer 11 like this, a pressure and a heat is applied to the semiconductor element 100 and thereby part of the layer 11b is extruded from the periphery of the layer 11a to the outside.

Therefore, as shown in FIG. 1B, at least part of the recess 102 (a portion where an end of the layer 11a is set further back to the inside than the end of the semiconductor element 100) can be filled with part of the layer 11b extruded from the periphery of the layer 11a to the outside.

Furthermore, since the viscosity of the layer 11a is set to such a viscosity as does not cause fluidity at the bonding temperature, the possibility can be reduced that the semiconductor element 100 is bonded obliquely or bonded out of alignment. Furthermore, the control of the thickness of the bonding layer 11 is easy as well. That is, since the layer 11a with a high viscosity at the bonding temperature is provided, high-precision bonding can be performed.

In this case, the thickness of the layer 11a is preferably thicker than the thickness of the layer 11b. Thereby, higher-precision bonding can be performed.

An example of the viscosities of the layers at the bonding temperature is illustrated as follows.

The viscosity of the layer 11a at the bonding temperature may be not less than 100 Pa·s and not more than 10,000 Pa·s.

In this case, the viscosity of the layer 11a at the bonding temperature is preferably not less than 250 Pa·s and less than 1000 Pa·s.

This is because setting the viscosity of the layer 11a not less than 250 Pa·s can sufficiently suppress the fluidity and ensure adhesiveness to the semiconductor element 100. Furthermore, this is also because setting the viscosity of the layer 11a less than 1000 Pa·s can ensure wettability at the bonding temperature. Such a configuration can suppress the semiconductor element 100 being bonded obliquely or bonded out of alignment. Moreover, since the generation of air bubbles can be suppressed in the layer 11a during bonding, the generation of voids can be suppressed as well.

Furthermore, if the viscosity of the layer 11a is set not less than 300 Pa·s and not more than 800 Pa·s, the effects described above can be enjoyed more surely.

The viscosity of the layer 11b at the bonding temperature may be not less than 0.1 Pa·s and less than 100 Pa·s.

In this case, the viscosity of the layer 11b at the bonding temperature is preferably not less than 15 Pa·s and not more than 90 Pa·s.

This is because, if the viscosity of the layer 11b is set less than 15 Pa·s, the fluidity at the bonding temperature becomes excessively high to possibly cause a large misalignment of the semiconductor element 100. Furthermore, this is because, even in the case where the misalignment of the semiconductor element 100 is small, minute voids may be generated. Furthermore, this is because setting the viscosity of the layer 11b not more than 90 Pa·s can ensure a sufficient fluidity at the bonding temperature to perform filling the recess 102 efficiently.

Moreover, if the viscosity of the layer 11b is set not less than 20 Pa·s and not more than 60 Pa·s, the effects described above can be enjoyed more surely.

These viscosities are those in the case of being measured with a dynamic viscoelasticity measurement apparatus (a parallel plate oscillatory rheometer), for example, the following measurement apparatus.

Measurement apparatus: Rheometer ARES (manufactured by Rheometric Scientific, Inc.)

Measurement type: parallel plate viscometer

Sample amount: 40 mg (gap: 0.3 to 0.7 mm)

Cone diameter: 8 mm

Angle: variable (strain control; automatically variable with the apparatus in accordance with viscosity)

Measurement temperature: 150° C./1.0 h+175° C./0.5 h

Frequency: 50 rad/s (single)

Load: the load during measurement in a temperature range of solid phases: 7.8 N (800 gf)

An example of the thicknesses of the layers is illustrated as follows. The thickness of the layer 11a may be not less than 1 μm (micrometer) and not more than 200 μm (micrometers), and the thickness of the layer 11b may be not less than 1 μm (micrometer) and not more than 200 μm (micrometers).

Next, the layer 11a and the layer 11b constituting the bonding layer 11 are further illustrated.

The layer 11a and the layer 11b can be formed by attaching a bonding agent in a film form to one surface of the wafer or the semiconductor element. Alternatively, the layer 11a and the layer 11b can be formed by forming what is called a die attachment film from a bonding agent and attaching this to one surface of the wafer or the semiconductor element.

As examples of the bonding agent, a material containing a resin that is a solute and a solvent can be given.

An insulative resin can be given as an example of the resin. A thermosetting resin, a thermoplastic resin, and the like can be given as examples of the insulative resin. In this case, a thermosetting resin such as an epoxy resin, acrylic resin, urethane resin, and silicon resin is preferable from the viewpoint of bonding conditions and heat resistance, and an epoxy resin is more preferable. Examples of the epoxy resin include a bisphenol A epoxy resin, bisphenol F epoxy resin, novolak epoxy resin, and the like. These resins may be used singly, or two or more of them may be mixed for use.

In regard to the solvent, a solvent capable of dissolving the resin that is a solute may be selected as appropriate. For example, γ-butyrolactone (GBL), cyclohexanone, isophorone, and the like are illustrated. These solvents may be used singly, or two or more of them may be mixed for use. An additive such as a known hardening accelerator, catalyst, filler, and coupling agent may be added as necessary.

Here, if there is unevenness in the bonding face of the bonding layer formed, air may get mixed in to generate voids when the semiconductor element is bonded to the matrix. The generation of such voids may cause a defect such as a decrease in the bonding strength. In this regard, by adding an additive having the function of suppressing the surface tension difference (leveling function), the unevenness in the bonding face of the bonding layer can be suppressed. As examples of the additive having the function of suppressing the surface tension difference, a silicon-based surface conditioner, acrylic surface conditioner, vinyl surface conditioner, and the like can be given. In this case, a silicon-based surface conditioner is preferably used which is highly effective in equalizing the surface tensions.

In this case, the viscosities of the layer 11a and the layer 11b at the bonding temperature can be controlled by conditions for producing a B-stage state. For example, the temperature, heating time, and the like during producing the B-stage state may be adjusted to control the viscosities of the layer 11a and the layer 11b. Furthermore, the viscosities of the layer 11a and the layer 11b at the bonding temperature can be controlled by the softening temperature or the melting temperature. For example, the softening temperature or the melting temperature may be adjusted by the component ratio of the bonding agents that form the layer 11a and the layer 11b or the like, and thereby the viscosities at the bonding temperature can be controlled. In this case, the softening temperatures or the melting temperatures of the layer 11a and the layer 11b may be adjusted by the type and/or amount of the resin that is a solute, the type and/or amount of the solvent, the type and/or amount of the additive, and the like, and thereby the viscosities at the bonding temperature can be controlled.

However, the manufacturing equipment, the manufacturing processes, and the like can be simplified by using a method in which the component ratio of the bonding agent used for the formation of the layer 11a and the component ratio of the bonding agent used for the formation of the layer 11b are made equal and the viscosities of the layer 11a and the layer 11b are controlled by conditions for producing the B-stage state.

Here, the case where the viscosities of the layer 11a and the layer 11b are controlled by conditions for producing the B-stage state will now be illustrated as an example.

Conditions for producing the B-stage state include the heating temperature and the heating time. In this case, the viscosities of the layer 11a and the layer 11b can be controlled by one of the heating temperature and the heating time, or by the heating temperature and the heating time.

For example, an epoxy resin is used as a solute of the bonding agent, γ-butyrolactone (GBL) is used as the solvent, the ratio of the epoxy resin in the bonding agent is set to 25 wt %, the diameter of the wafer is set to about 30 mm (millimeters), the thickness of the layer 11a is set to about 7 μm (micrometers), and the thickness of the layer 11b is set to about 3 μm (micrometers).

In this case, as conditions for producing the B-stage state, it is possible to set the heating temperature of the layer 11a to about 90° C., the heating time thereof to about 45 minutes, the heating temperature of the layer 11b to about 90° C., and the heating time thereof to about 15 minutes.

Producing the B-stage state under such conditions makes it possible to make the viscosity of the layer 11a at the bonding temperature (about 175° C.) about 300 Pa·s and the viscosity of the layer 11b at the bonding temperature about 30 Pa·s. These viscosities are those in the case of being measured with a dynamic viscoelasticity measurement apparatus (a parallel plate oscillatory rheometer).

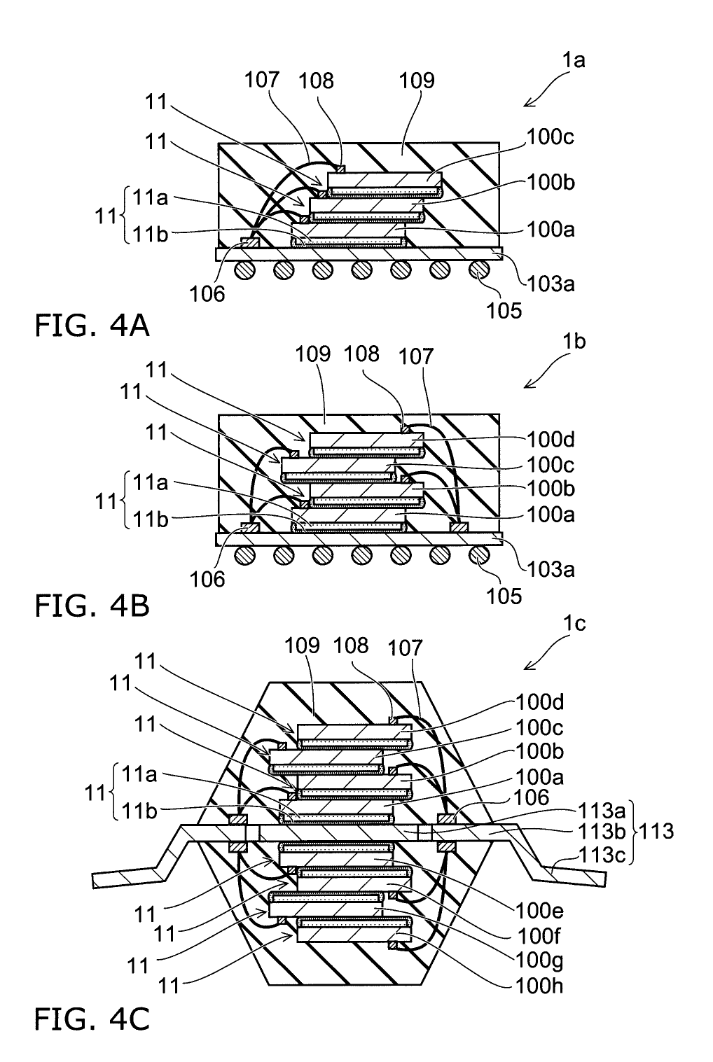

FIGS. 4A to 4C are schematic cross-sectional views for illustrating the case of an application to a semiconductor device of a stacked multichip structure (a stacked semiconductor device). The surface protection films illustrated in FIG. 3 are omitted to avoid complication.

As shown in FIG. 4A, a matrix 103a is provided in a semiconductor device 1a. The matrix 103a may be an insulating substrate such as a resin substrate, ceramic substrate, and glass substrate, for example. In this case, the resin substrate may be a mutilayer copper-clad laminate substrate (a multilayer printed circuit substrate) or the like. External connection terminals 105 such as solder bumps are provided on the opposite side of the matrix 103a from the side on which semiconductor elements are bonded.

An electrode unit 106 electrically connected to the external connection terminal 105 is provided on the side of the matrix 103a on which semiconductor elements are bonded. Semiconductor elements 100a to 100c are bonded to the matrix 103a via the bonding layer 11 (the layer 11a and the layer 11b) so as to be stacked on the matrix 103a. Electrode pads 108 provided at the semiconductor elements 100a to 100c and the electrode unit 106 are electrically connected via bonding wires 107. A resin sealing unit 109 is provided so as to cover the bonding layers 11, the semiconductor elements 100a to 100c, the electrode unit 106, the bonding wires 107, and the electrode pads 108. The resin sealing unit 109 may be made of, for example, an epoxy resin or the like.

In this case, the number, stacking manner, and the like of semiconductor elements may be appropriately altered as well.

For example, a semiconductor device 1b may be fabricated in which four semiconductor elements 100a to 100d are stacked to be displaced alternately as shown in FIG. 4B, or they may be stacked to be displaced in one direction or folded back at a step on the way.

As shown in FIG. 4C, a matrix 113 is provided in a semiconductor device 1c. The matrix 113 may be, for example, a lead frame or the like made of a copper alloy, iron alloy, or the like. A die pad 113a, an inner lead 113b, and an outer lead 113c are provided in the matrix 113. Semiconductor elements 100a to 100h are bonded to both surfaces of the die pad 113a so as to be stacked thereon. The electrode unit 106 electrically connected to the outer lead 113c is provided at the inner lead 113b. The outer lead 113c has the function of the external connection terminal 105 described above. The electrode pads 108 provided at the semiconductor elements 100a to 100h and the electrode units 106 are electrically connected via the bonding wires 107. The resin sealing unit 109 is provided so as to cover the bonding layers 11, the semiconductor elements 100a to 100h, the electrode units 106, the bonding wires 107, and the electrode pads 108. The resin sealing unit 109 may be made of, for example, an epoxy resin or the like. The number, stacking manner, and the like of semiconductor elements may be appropriately altered as well. Although what are illustrated in FIGS. 4A to 4C are semiconductor devices of a stacked multichip structure, also a semiconductor device may be fabricated in which semiconductor elements are arranged planarly. For example, a semiconductor device in which one semiconductor element is bonded to one surface of the matrix may be fabricated.

Next, a modification according to the embodiment will now be illustrated.

### First Modification

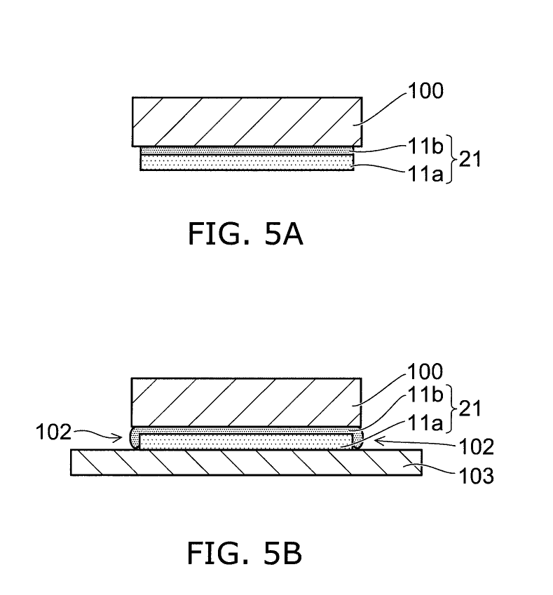

FIGS. 5A and 5B are schematic views for illustrating a semiconductor device according to a first modification. FIG. 5A is a schematic view before bonding to the matrix, and FIG. 5B is a schematic view after bonding to the matrix.

Also in the first modification, a bonding layer 21 is formed of a plurality of layers with different viscosities at the bonding temperature. In the bonding layer 21, however, the order of stacking the layer 11a and the layer 11b is different from that of the bonding layer 11 illustrated in FIGS. 1A and 1B. That is, although the layer 11b with a low viscosity is provided on the side bonded to the matrix in the bonding layer 11 illustrated in FIG. 1A, the layer 11a with a high viscosity is provided on the side bonded to the matrix in the bonding layer 21, as illustrated in FIG. 5A.

When the semiconductor element 100 is bonded to the matrix 103 via the bonding layer 21 like this, a pressure is applied to the semiconductor element and thereby part of the layer 11b is extruded from the periphery of the layer 11a to the outside.

Therefore, as shown in FIG. 5B, at least part of the recess 102 can be filled with part of the layer 11b extruded from the periphery of the layer 11a to the outside.

Furthermore, since the viscosity of the layer 11a is set to such a viscosity as does not cause fluidity at the bonding temperature, the possibility can be reduced that the semiconductor element 100 is bonded obliquely or bonded out of alignment. Furthermore, the control of the thickness of the bonding layer 21 is easy as well. That is, since the layer 11a with a high viscosity at the bonding temperature is provided, high-precision bonding can be performed.

In this case, the thickness of the layer 11a is preferably thicker than the thickness of the layer 11b. Thereby, higher-precision bonding can be performed.

The material, the control of the viscosity, and the like of the layer 11a and the layer 11b constituting the bonding layer 21 are similar to the case of the bonding layer 11 described above, and a description thereof is therefore omitted.

### Second Modification

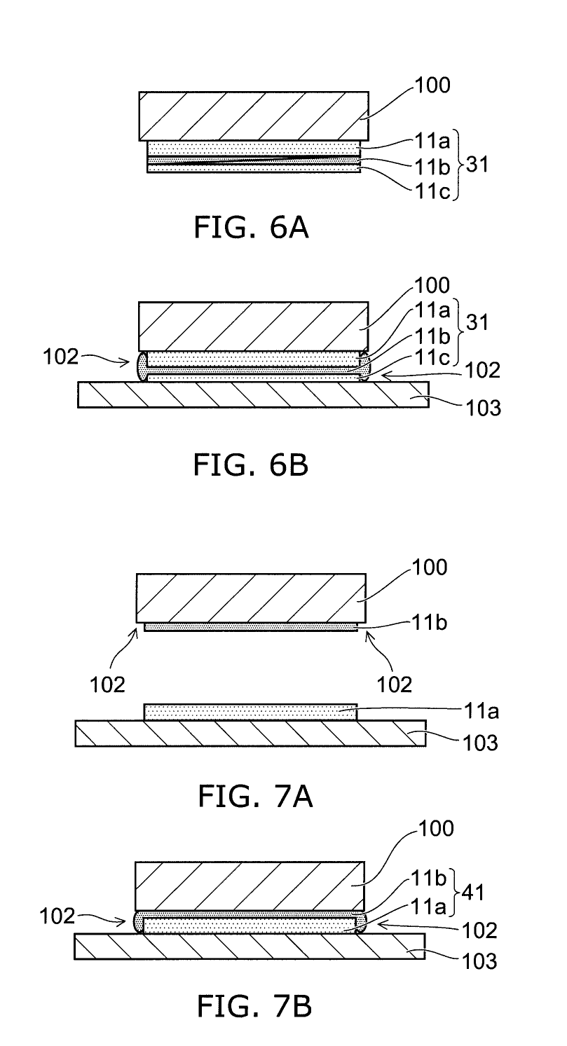

FIGS. 6A and 6B are schematic views for illustrating a semiconductor device according to a second modification. FIG. 6A is a schematic view before bonding to the matrix, and FIG. 6B is a schematic view after bonding to the matrix.

Also in the second modification, a bonding layer 31 is formed of a plurality of layers with different viscosities at the bonding temperature. The bonding layer 31, however, has a difference from the bonding layer 11 illustrated in FIGS. 1A and 1B in that a layer 11c (third layer) is further provided on the side bonded to the matrix. That is, the layer 11c having a viscosity higher than the viscosity of the layer 11b at the bonding temperature is further provided on the opposite side of the layer 11b from the layer 11a.

The layer 11c has a viscosity higher than the viscosity of the layer 11b at the bonding temperature. That is, the layer 11c having a viscosity higher than the viscosity of the layer 11b at the bonding temperature is further provided on the opposite side of the layer 11b from the layer 11a.

In this case, the viscosity of the layer 11c may be set to such a viscosity as does not cause fluidity at the bonding temperature. The viscosity of the layer 11a and the viscosity of the layer 11c at the bonding temperature may be equal or different.

When the semiconductor element 100 is bonded to the matrix 103 via the bonding layer 31 like this, a pressure is applied to the semiconductor element 100 and thereby part of the layer 11b is extruded from the peripheries of the layer 11a and the layer 11c to the outside.

Therefore, as shown in FIG. 6B, at least part of the recess 102 can be filled with part of the layer 11b extruded from the peripheries of the layer 11a and the layer 11c to the outside.

Furthermore, since the viscosities of the layer 11a and the layer 11c are set to such viscosities as do not cause fluidity at the bonding temperature, the possibility can be reduced that the semiconductor element 100 is bonded obliquely or bonded out of alignment. Furthermore, the control of the thickness of the bonding layer 31 is easy as well. That is, since the layer 11a and the layer 11c with high viscosities at the bonding temperature are provided, high-precision bonding can be performed.

In this case, the thickness of the layer 11a is preferably thicker than the thickness of the layer 11b. Thereby, higher-precision bonding can be performed.

The thickness of the layer 11c is preferably thinner than the thickness of the layer 11a. Thereby, since heat can be efficiently conducted to the layer 11b via the layer 11c, the time of filling the recess 102 can be shortened.

An example of the viscosities of the layers at the bonding temperature is illustrated as follows. The viscosity of the layer 11a may be not less than 100 Pa·s and not more than 10,000 Pa·s. The viscosity of the layer 11b may be not less than 0.1 Pa·s and less than 100 Pa·s. The viscosity of the layer 11c may be not less than 100 Pa·s and not more than 10,000 Pa·s.

In this case, similarly to the case described above, the viscosity of the layer 11a at the bonding temperature is preferably not less than 250 Pa·s and less than 1000 Pa·s, and more preferably not less than 300 Pa·s and not more than 800 Pa·s.

The viscosity of the layer 11b at the bonding temperature is preferably not less than 15 Pa·s and not more than 90 Pa·s, and more preferably not less than 20 Pa·s and not more than 60 Pa·s.

The viscosity of the layer 11c at the bonding temperature is preferably not less than 250 Pa·s and less than 1000 Pa·s, and more preferably not less than 300 Pa·s and not more than 800 Pa·s. The preferable range of the viscosity of the layer 11c is similar to the case of the layer 11a, and a description thereof is therefore omitted.

These viscosities are those in the case of being measured with a dynamic viscoelasticity measurement apparatus (a parallel plate oscillatory rheometer), for example, the following measurement apparatus.

Measurement apparatus: Rheometer ARES (manufactured by Rheometric Scientific, Inc.)

Measurement type: parallel plate viscometer

Sample amount: 40 mg (gap: 0.3 to 0.7 mm)

Cone diameter: 8 mm

Angle: variable (strain control; automatically variable with apparatus in accordance with viscosity)

Measurement temperature: 150° C./1.0 h+175° C./0.5 h

Frequency: 50 rad/s (single)

Load: the load during measurement in a temperature range of solid phases: 7.8 N (800 gf)

An example of the thicknesses of the layers is illustrated as follows. The thickness of the layer 11a may be not less than 1 μm (micrometer) and not more than 100 μm (micrometers), the thickness of the layer 11b may be not less than 1 μm (micrometer) and not more than 100 μm (micrometers), and the thickness of the layer 11c may be not less than 1 μm (micrometer) and not more than 100 μm (micrometers).

In this case, the material, the control of the viscosity, and the like of the layer 11a, the layer 11b, and the layer 11c constituting the bonding layer 31 may be similar to the case of the bonding layer 11 described above. Furthermore, the layer 11a and the layer 11c may be similar as well. Therefore, a description of the material, the control of the viscosity, and the like of the layer 11a, the layer 11b, and the layer 11c is omitted.

Here, as an example, the case will now be illustrated where the viscosities of the layer 11a, the layer 11b, and the layer 11c are controlled by conditions for producing the B-stage state.

For example, an epoxy resin is used as a solute of the bonding agent, γ-butyrolactone (GBL) is used as the solvent, the ratio of the epoxy resin in the bonding agent is set to 25 wt %, the diameter of the wafer is set to about 30 mm (millimeters), the thickness of the layer 11a is set to about 5 μm (micrometers), the thickness of the layer 11b is set to about 3 μm (micrometers), and the thickness of the layer 11c is set to about 2 (micrometers).

In this case, as conditions for producing the B-stage state, it is possible to set the heating temperature of the layer 11a to about 90° C., the heating time thereof to about 45 minutes, the heating temperature of the layer 11b to about 90° C., the heating time thereof to about 15 minutes, the heating temperature of the layer 11c to about 80° C., and the heating time thereof to about one hour. In regard to the layer 11c, it is also possible to further use a UV-cured resin to cure the surface.

Producing the B-stage state under such conditions makes it possible to make the viscosity of the layer 11a at the bonding temperature (about 175° C.) about 500 Pa·s, the viscosity of the layer 11b at the bonding temperature about 50 Pa·s, and the viscosity of the layer 11c at the bonding temperature about 200 Pa·s. These viscosities are those in the case of being measured with a dynamic viscoelasticity measurement apparatus (a parallel plate oscillatory rheometer).

### Third Modification

FIGS. 7A and 7B are schematic views for illustrating a semiconductor device according to a third modification. FIG. 7A is a schematic view before bonding to the matrix, and FIG. 7B is a schematic view after bonding to the matrix.

Also in the third modification, a bonding layer is formed of a plurality of layers with different viscosities at the bonding temperature. However, in a bonding layer 41, the positions in which the layer 11a and the layer 11b are formed are different from those of the bonding layer 11 illustrated in FIGS. 1A and 1B. That is, in the bonding layer 11 illustrated in FIG. 1A, the layer 11a and the layer 11b are formed so as to be stacked, but in the bonding layer 41, the layer 11b is formed on one surface of the semiconductor element 100 and the layer 11a is formed on the matrix 103, as illustrated in FIG. 7A. Then, as shown in FIG. 7B, the layer 11a and the layer 11b are bonded to form the bonding layer 41 when the semiconductor element 100 is bonded to the matrix 103.

When the layer 11a and the layer 11b are bonded to form the bonding layer 41, part of the layer 11b is extruded from the periphery of the layer 11a to the outside.

Therefore, as shown in FIG. 7B, at least part of the recess 102 can be filled with part of the layer 11b extruded from the periphery of the layer 11a to the outside.

Furthermore, since the viscosity of the layer 11a is set to such a viscosity as does not cause fluidity at the bonding temperature, the possibility can be reduced that the semiconductor element 100 is bonded obliquely or bonded out of alignment. Furthermore, the control of the thickness of the bonding layer 41 is easy as well. That is, since the layer 11a with a high viscosity at the bonding temperature is provided, high-precision bonding can be performed.

In this case, the thickness of the layer 11a is preferably thicker than the thickness of the layer 11b. Thereby, higher-precision bonding can be performed.

The material, the control of the viscosity, and the like of the layer 11a and the layer 11b that form the bonding layer 41 are similar to the case of the bonding layer 11 described above, and a description thereof is therefore omitted.

Also a configuration is possible in which the layer 11a is formed on one surface of the semiconductor element 100 and the layer 11b is formed on the matrix 103. Furthermore, in the case of a bonding layer formed of three or more layers like what is illustrated in FIGS. 6A and 6B, the layers may be formed to be sorted to the semiconductor element 100 and the matrix 103.

### Fourth Modification

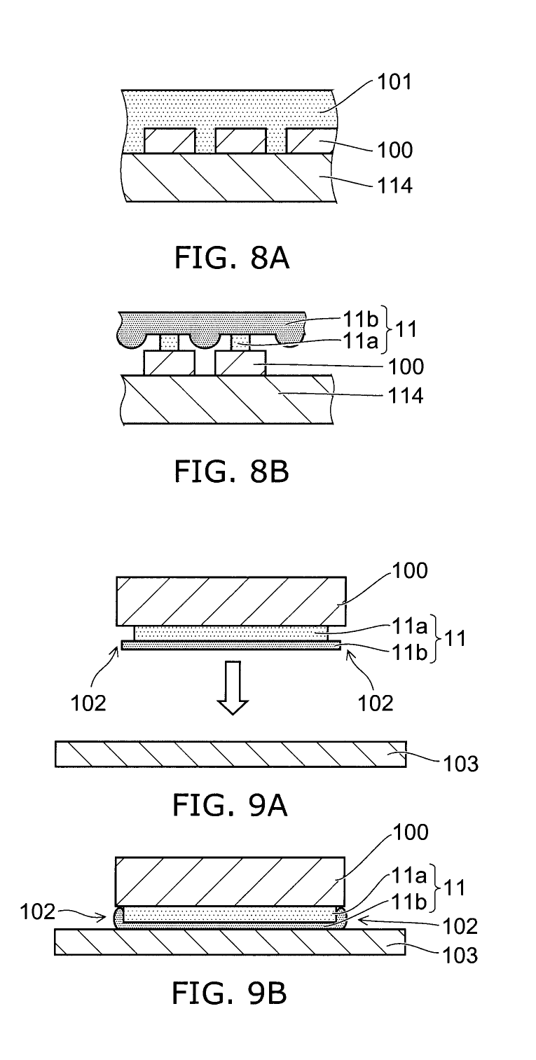

FIG. 8A is a schematic view for illustrating a semiconductor device according to a comparative example, and FIG. 8B is a schematic view for illustrating a semiconductor device according to a fourth modification.

FIG. 9A is a schematic view before bonding to the matrix, and FIG. 9B is a schematic view after bonding to the matrix.

In what is called the dicing-before-grinding method, a surface protection tape 114 is attached to a surface (a surface in which a circuit pattern is formed) of a wafer, and a bonding layer is formed on the back surface (the surface opposite to the surface in which a circuit pattern is formed) of a semiconductor element 100 fragmentated by dicing.

Here, when a bonding agent is attempted to be attached to the back surface of the semiconductor element 100 fragmentated by dicing, the bonding agent may also get between semiconductor elements 100.

If the bonding agent is turned into the B-stage state in a state where the bonding agent exists between semiconductor elements 100, there is a case where a bonding layer 101 bonded also to the surface protection tape 114 is formed, as shown in FIG. 8A.

In this case, although the surface protection tape 114 needs to be removed before performing die bonding, it is difficult to remove the surface protection tape 114 if the surface protection tape 114 and the bonding layer 101 are bonded.

In view of this, in the embodiment, the layer 11a smaller than the end portion of the semiconductor element 100 is formed, and the layer 11b is formed so as to be stacked on the layer 11a.

In this case, since the layer 11a is configured to be smaller than the end portion of the semiconductor element 100, the layer 11a is prevented from being formed so as to get between semiconductor elements 100 to be bonded to the surface protection tape 114.

The layer 11a like this can be formed by, for example, a method in which the ink jet method or the like is used to attach a bonding agent in a line configuration along a prescribed cutting position and the bonding agent is turned into the B-stage state.

When the layer 11b is formed so as to be stacked on the layer 11a like this, the presence of the layer 11a underlying can suppress the bonding agent getting between semiconductor elements 100.

Consequently, since the bonding of the surface protection tape 114 and the bonding layer 11 can be suppressed, the surface protection tape 114 can be removed easily.

Although the layer 11b is formed so as to be provided continuously, since the viscosity of the layer 11b is set to such a viscosity as causes a certain level of fluidity at the bonding temperature, the layer 11b can be torn to be separated when the semiconductor element 100 is picked up.

Here, since the layer 11a is configured to be smaller than the end portion of the semiconductor element 100, the recess 102 is necessarily formed as shown in FIG. 9A.

However, as shown in FIG. 9B, at least part of the recess 102 is still filled with part of the layer 11b extruded from the periphery of the layer 11a to the outside when the semiconductor element 100 is bonded to the matrix 103 via the bonding layer 11.

Conditions for forming the layer 11a and the layer 11b and the like are similar to those of what is illustrated in FIGS. 1A and 1B, and a description thereof is therefore omitted.

Next, a method for manufacturing a semiconductor device according to a second embodiment will now be illustrated.

### SECOND EMBODIMENT

The manufacturing processes of a semiconductor device include the process of forming a circuit pattern on a surface of a wafer by film-formation, resist application, exposure, development, etching, resist removal, and the like in what is called a pre-process, and the processes of inspection, cleaning, heat treatment, impurity introduction, diffusion, planarization, and the like. What is called a post-process includes the dicing process, the die bonding process, the bonding process, the constituting process such as the sealing process, the inspection process of inspecting functions and reliability, and the like.

In the method for manufacturing a semiconductor device according to the embodiment, a bonding layer formed of a plurality of layers with different viscosities at the bonding temperature is formed on one surface of a wafer or a semiconductor element before or after the dicing process. Then, the semiconductor element on which such a bonding layer is formed is bonded to a matrix in the die bonding process. Known technology can be applied to this embodiment except that the bonding layer formed of a plurality of layers with different viscosities at the bonding temperature is formed on one surface of the wafer or the semiconductor element, and a description of the processes described above is therefore omitted.

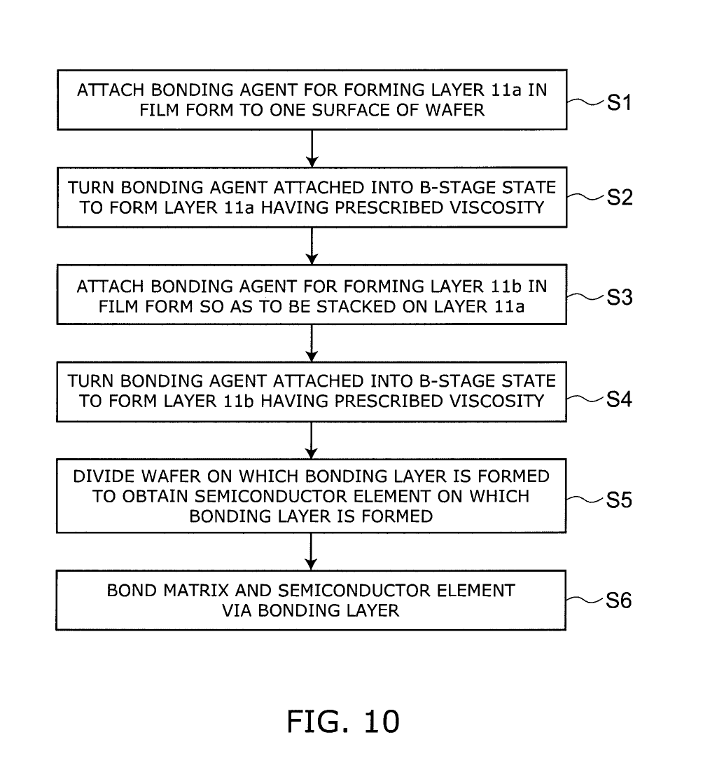

FIG. 10 is a flow chart illustrating the method for manufacturing a semiconductor device according to the second embodiment.

FIG. 10 illustrates the case where a bonding layer formed of the layer 11a and the layer 11b with different viscosities at the bonding temperature is formed on one surface of a wafer before the dicing process, as an example. Further, FIG. 10 illustrates the case where the viscosities of the layer 11a and the layer 11b at the bonding temperature are controlled by conditions for producing the B-stage state.

First, a bonding agent for forming the layer 11a is attached in a film form to one surface (e.g. the back surface (the surface opposite to a surface in which a circuit pattern is formed)) of the wafer (step S1).

At this time, the thickness of the bonding agent attached is made a prescribed dimension so that the layer 11a may be formed with a prescribed thickness.

The thickness of the layer 11a may be made thicker than the thickness of the layer 11b, as described above.

As examples of the method for attaching the bonding agent in a film form, the ink jet method, spray method, roll coater method, screen printing method, and the like can be given. In this case, the ink jet method and the spray method, which can attach the bonding agent in a film form in a noncontact state, are preferable, and the ink jet method, which can form a thin film with a uniform thickness, is more preferable.

Next, the bonding agent attached is turned into the B-stage state to form the layer 11a having a prescribed viscosity (step S2).

At this time, the viscosity at the bonding temperature is controlled to a prescribed value by conditions for producing the B-stage state.

For example, the viscosity of the layer 11a is controlled by the temperature, heating time, and the like when producing the B-stage state. In this case, for example, the viscosity at the bonding temperature is controlled to not less than 100 Pa·s and not more than 10,000 Pa·s. As described above, the viscosity of the layer 11a at the bonding temperature may be set not less than 250 Pa·s and less than 1000 Pa·s, or not less than 300 Pa·s and not more than 800 Pa·s.

Next, a bonding agent for forming the layer 11b is attached in a film form so as to be stacked on the layer 11a (step S3).

At this time, the thickness of the bonding agent attached is made a prescribed dimension so that the layer 11b may be formed with a prescribed thickness.

Next, the bonding agent attached is turned into the B-stage state to form the layer 11b having a prescribed viscosity (step S4).

At this time, the viscosity at the bonding temperature is controlled to a prescribed value by conditions for producing the B-stage state.

That is, the layer 11b having a viscosity lower than the viscosity of the layer 11a at the bonding temperature is formed.

For example, the viscosity of the layer 11b is controlled by the temperature, heating time, and the like when producing the B-stage state. In this case, for example, the viscosity at the bonding temperature is controlled to not less than 0.1 Pa·s and less than 100 Pa·s. As described above, the viscosity of the layer 11b at the bonding temperature may be set not less than 15 Pa·s and not more than 90 Pa·s, or not less than 20 Pa·s and not more than 60 Pa·s.

Next, the blade dicing method or the like is used in the dicing process to divide the wafer on which the bonding layer is formed to obtain a semiconductor element on which the bonding layer is formed (step S5).

Next, the matrix 103 and the semiconductor element 100 are bonded via the bonding layer 11 in the die bonding process (step S6).

At this time, the end of the layer 11a has a portion (the recess 102) set further back to the inside than the end of the semiconductor element 100, and at least part of the portion set back to the inside is filled with part of the layer 11b extruded from the periphery of the layer 11a to the outside.

Here, as an example, specific conditions for producing the B-stage state are illustrated.

For example, an epoxy resin is used as a solute of the bonding agent, γ-butyrolactone (GBL) is used as the solvent, the ratio of the epoxy resin in the bonding agent is set to 25 wt %, the diameter of the wafer is set to about 30 mm (millimeters), the thickness of the layer 11a is set to about 7 μm (micrometers), and the thickness of the layer 11b is set to about 3 μm (micrometers).

In this case, as conditions for producing the B-stage state, it is possible to set the heating temperature of the layer 11a to about 90° C., the heating time thereof to about 45 minutes, the heating temperature of the layer 11b to about 90° C., and the heating time thereof to about 15 minutes.

Producing the B-stage state under such conditions makes it possible to make the viscosity of the layer 11a at the bonding temperature (about 175° C.) about 300 Pa·s, and the viscosity of the layer 11b at the bonding temperature about 30 Pa·s. These viscosities are those in the case of being measured with a dynamic viscoelasticity measurement apparatus (a parallel plate oscillatory rheometer).

### First Modification

Although the foregoing is the case where the viscosities of the layer 11a and the layer 11b at the bonding temperature are controlled by conditions for producing the B-stage state, the viscosities of the layer 11a and the layer 11b at the bonding temperature can be controlled by the softening temperature or the melting temperature.

First, a bonding agent for forming the layer 11a is attached in a film form to one surface (e.g. the back surface (the surface opposite to a surface in which a circuit pattern is formed)) of a wafer (step S1-1).

At this time, the viscosity at the bonding temperature is controlled to a prescribed value by the softening temperature or the melting temperature. The softening temperature or the melting temperature may be adjusted by, for example, the component ratio and the like of a bonding agent that forms the layer 11a to control the viscosity at the bonding temperature. In this case, the softening temperature or the melting temperature of the layer 11a may be adjusted by the type and/or amount of the resin that is a solute, the type and/or amount of the solvent, the type and/or amount of the additive, and the like to control the viscosity at the bonding temperature. The viscosity at the bonding temperature is controlled to, for example, not less than 100 Pa·s and not more than 10,000 Pa·s. As described above, the viscosity of the layer 11a at the bonding temperature may be set not less than 250 Pa·s and less than 1000 Pa·s, or not less than 300 Pa·s and not more than 800 Pa·s.

The thickness of the bonding agent attached is made a prescribed dimension so that the layer 11a may be formed with a prescribed thickness.

As described above, the thickness of the layer 11a may be made thicker than the thickness of the layer 11b.

Next, the bonding agent attached is turned into the B-stage state (step S2-1).

At this time, the viscosity at the bonding temperature may be further controlled by conditions for producing the B-stage state.

Next, a bonding agent for forming the layer 11b is attached in a film form so as to be stacked on the layer 11a (step S3-1).

At this time, the viscosity at the bonding temperature is controlled to a prescribed value by the softening temperature or the melting temperature. In this case, for example, the viscosity at the bonding temperature is controlled to not less than 0.1 Pa·s and less than 100 Pa·s. As described above, the viscosity of the layer 11b at the bonding temperature may be set not less than 15 Pa·s and not more than 90 Pa·s, or not less than 20 Pa·s and not more than 60 Pa·s.

The thickness of the bonding agent attached is made a prescribed dimension so that the layer 11b may be formed with a prescribed thickness.

Next, the bonding agent attached is turned into the B-stage state (step S4-1).

At this time, the viscosity at the bonding temperature may be further controlled by conditions for producing the B-stage state.

Next, the blade dicing method or the like is used in the dicing process to divide the wafer on which the bonding layer is formed to obtain a semiconductor element on which the bonding layer is formed (step S5-1).

Next, the matrix 103 and the semiconductor element 100 are bonded via the bonding layer 11 in the die bonding process (step S6-1).

At this time, the end of the layer 11a has a portion (the recess 102) set further back to the inside than the end of the semiconductor element 100, and at least part of the portion set back to the inside is filled with part of the layer 11b extruded from the periphery of the layer 11a to the outside.

### Second Modification

Although the foregoing is the case where the bonding layer is formed on one surface of the wafer, also a method is possible in which what is called a die attachment film is formed from a bonding agent and this is attached to one surface of a wafer or a semiconductor element to form a bonding layer.

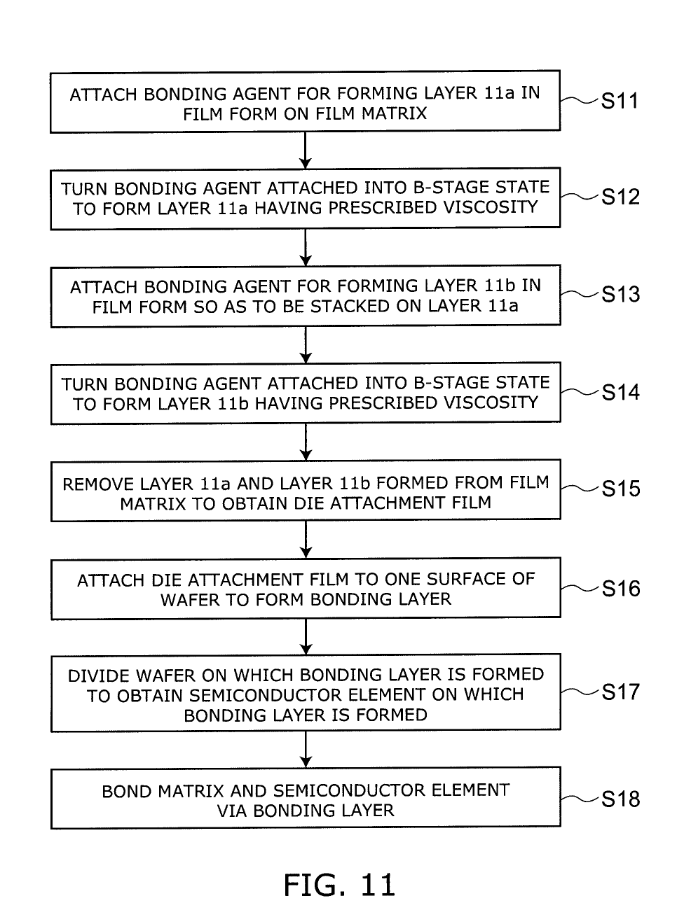

FIG. 11 is a flow chart illustrating a method for manufacturing a semiconductor device according to a second modification.

First, a bonding agent for forming the layer 11a is attached in a film form onto a film matrix serving as a supporting body (step S11).

At this time, the thickness of the bonding agent attached is made a prescribed dimension so that the layer 11a may be formed with a prescribed thickness.

As described above, the thickness of the layer 11a may be made thicker than the thickness of the layer 11b.

As examples of the method for attaching the bonding agent in a film form, the ink jet method, spray method, roll coater method, screen printing method, and the like can be given. In this case, the ink jet method and the spray method, which can attach the bonding agent in a film form in a noncontact state, are preferable, and the ink jet method, which can form a thin film with a uniform thickness, is more preferable.

Next, the bonding agent attached is turned into the B-stage state to form the layer 11a having a prescribed viscosity (step S12).

At this time, the viscosity at the bonding temperature is controlled to a prescribed value by conditions for producing the B-stage state.

For example, the viscosity of the layer 11a is controlled by the temperature, heating time, and the like when producing the B-stage state. In this case, for example, the viscosity at the bonding temperature is controlled to not less than 100 Pa·s and not more than 10,000 Pa·s. As described above, the viscosity of the layer 11a at the bonding temperature may be set not less than 250 Pa·s and less than 1000 Pa·s, or not less than 300 Pa·s and not more than 800 Pa·s.

Next, a bonding agent for forming the layer 11b is attached in a film form so as to be stacked on the layer 11a (step S13).

At this time, the thickness of the bonding agent attached is made a prescribed dimension so that the layer 11b may be formed with a prescribed thickness.

Next, the bonding agent attached is turned into the B-stage state to form the layer 11b having a prescribed viscosity (step S14).

At this time, the viscosity at the bonding temperature is controlled to a prescribed value by conditions for producing the B-stage state.

For example, the viscosity of the layer 11b is controlled by the temperature, heating time, and the like when producing the B-stage state. In this case, for example, the viscosity at the bonding temperature is controlled to not less than 0.1 Pa·s and less than 100 Pa·s. As described above, the viscosity of the layer 11b at the bonding temperature may be set not less than 15 Pa·s and not more than 90 Pa·s, or not less than 20 Pa·s and not more than 60 Pa·s.

The layer 11a and the layer 11b thus formed are removed from the film matrix to obtain a die attachment film (step S15).

Next, the die attachment film formed of the layer 11a and the layer 11b is attached to one surface of a wafer to form the bonding layer 11 (step S16).

The laminating method, for example, may be used to attach the die attachment film to one surface of the wafer.

Next, the blade dicing method or the like is used in the dicing process to divide the wafer on which the bonding layer 11 is formed to obtain a semiconductor element on which the bonding layer 11 is formed (step S17).

Next, the matrix 103 and the semiconductor element 100 are bonded via the bonding layer 11 in the die bonding process (step S18).

At this time, the end of the bonding layer 11a has a portion (the recess 102) set further back to the inside than the end of the semiconductor element 100, and at least part of the portion set back to the inside is filled with part of the layer 11b extruded from the periphery of the layer 11a to the outside.

Although the foregoing is the case where the viscosities of the layer 11a and the layer 11b at the bonding temperature are controlled by conditions for producing the B-stage state, the viscosities of the layer 11a and the layer 11b at the bonding temperature can be controlled also by the softening temperature or the melting temperature.

The point that the viscosities of the layer 11a and the layer 11b at the bonding temperature are controlled by the softening temperature or the melting temperature is similar to what is described above and a description thereof is therefore omitted.

Although what is illustrated above is the case where the semiconductor element on which the bonding layer is formed is obtained by performing dicing on the wafer on which the bonding layer is formed, the embodiment is not limited thereto. For example, a method is possible in which what is called dicing before grinding is performed and a bonding layer is formed on one surface of a semiconductor element fragmentated.

Furthermore, although the case of the bonding layer formed of the layer 11a and the layer 11b has been illustrated, a bonding layer formed of three or more layers is possible. In this case, the processes described above may be repeated to sequentially stack layers with different viscosities at the bonding temperature.

Furthermore, although the case where the layer 11b is stacked on the layer 11a has been illustrated, the layer 11a may be stacked on the layer 11b, as in the case of what is illustrated in FIGS. 5A and 5B.

Furthermore, also a method is possible in which a die attachment film formed of the layer 11a and a die attachment film formed of the layer 11b are formed, and then, like what is illustrated in FIG. 7A, the die attachment film formed of the layer 11b is attached to one surface of the semiconductor element 100 and the die attachment film formed of the layer 11a is attached to the matrix 103. Then, as shown in FIG. 7B, the layer 11a and the layer 11b may be bonded to form the bonding layer 41 when the semiconductor element 100 is bonded to the matrix 103.

In this case, also a method is possible in which the die attachment film formed of the layer 11a is attached to one surface of the semiconductor element 100 and the die attachment film formed of the layer 11b is attached to the matrix 103. Moreover, in the case of a bonding layer formed of three or more layers, the layers may be sorted to form die attachment films.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising a matrix and a semiconductor element bonded to the matrix via a bonding layer,
the bonding layer including a first layer and a second layer having a viscosity lower than a viscosity of the first layer at a bonding temperature,
the first layer having a portion in which an end of the first layer is set further back to an inside than an end of the semiconductor element, and
at least a part of the portion set back to the inside being filled with a part of the second layer extruded from a periphery of the first layer to an outside.

2. The device according to claim 1, wherein a viscosity of the second layer at a bonding temperature is a viscosity causing fluidity at the bonding temperature.

3. The device according to claim 1, wherein a viscosity of the first layer at a bonding temperature is a viscosity not causing fluidity at the bonding temperature.

4. The device according to claim 1, wherein a viscosity of the second layer at a bonding temperature is not less than 0.1 Pa·s and less than 100 Pa·s.

5. The device according to claim 1, wherein a viscosity of the first layer at a bonding temperature is not less than 100 Pa·s and not more than 10000 Pa·s.

6. The device according to claim 1, wherein a thickness of the first layer is thicker than a thickness of the second layer.

7. The device according to claim 1, wherein the bonding layer further includes a third layer provided on an opposite side of the second layer from the first layer and having a viscosity higher than a viscosity of the second layer at a bonding temperature.

8. The device according to claim 7, wherein a viscosity of the third layer at a bonding temperature is a viscosity not causing fluidity at the bonding temperature.

9. The device according to claim 7, wherein a viscosity of the third layer at a bonding temperature is not less than 100 Pa·s and not more than 10000 Pa·s.

10. The device according to claim 7, wherein a thickness of the third layer is thinner than a thickness of the first layer.

11. A method for manufacturing a semiconductor device including bonding a matrix and a semiconductor element via a bonding layer,
the method comprising:
forming a first layer that forms the bonding layer; and
forming a second layer having a viscosity lower than a viscosity of the first layer that forms the bonding layer at a bonding temperature,
the first layer being formed so that an end of the first layer has a portion set further back to an inside than an end of the semiconductor element, and
at least a part of the portion set back to the inside being filled with a part of the second layer extruded from a periphery of the first layer to an outside in bonding the matrix and the semiconductor element via the bonding layer.

12. The method according to claim 11, wherein a viscosity of the second layer at a bonding temperature is set to a viscosity causing fluidity at the bonding temperature in the forming the second layer.

13. The method according to claim 11, wherein a viscosity of the first layer at the bonding temperature is set to a viscosity not causing fluidity at the bonding temperature in the forming the first layer.

14. The method according to claim 11, wherein a viscosity of the second layer at a bonding temperature is set not less than 0.1 Pa·s and less than 100 Pa·s in the forming the second layer.

15. The method according to claim 11, wherein a viscosity of the first layer at the bonding temperature is set not less than 100 Pa·s and not more than 10000 Pa·s in the forming the first layer.

16. The method according to claim 12, wherein the viscosity of the second layer at the bonding temperature is adjusted by at least one selected from the group consisting of a condition for producing a B-stage state, a softening temperature, and a melting temperature.

17. The method according to claim 13, wherein the viscosity of the first layer at the bonding temperature is adjusted by at least one selected from the group consisting of a condition for producing a B-stage state, a softening temperature, and a melting temperature.

18. The method according to claim 11, wherein the first layer is formed so as to have a thickness thicker than a thickness of the second layer in the forming the first layer.

19. The method according to claim 11, wherein the forming the first layer and the forming the second layer are performed above one surface of a wafer or the semiconductor element.

20. The method according to claim 11, wherein a die attachment film is formed by performing the forming the first layer and the forming the second layer and the die attachment film is attached to one surface of a wafer or the semiconductor element.
